(19) United States
(12) Patent Application Publication
(10) Pub. No.: US 2011/0023951 A1
(43) Pub. Date: Feb. 3, 2011

(54) PHOTOVOLTAIC CELL SUBSTRATE, METHOD OF MANUFACTURING THE PHOTOVOLTAIC CELL SUBSTRATE, AND PHOTOVOLTAIC CELL

(75) Inventors: Je Choon Ryoo, ChungCheongNam-Do (KR); Dong Woo Kim, ChungCheongNam-Do (KR); Seo Hyun Kim, ChungCheongNam-Do (KR)

Correspondence Address: LERNER, DAVID, LITTENBERG,;KRUMHOLZ & MENTLIK, 600 SOUTH AVENUE WEST, WESTFIELD, NJ, 07090, US

(73) Assignee: SAMSUNG CORNING PRECISION MATERIALS CO., LTD., Gyeongsangbuk-do (KR)

(21) Appl. No.: 12/845,010

(22) Filed: Jul. 28, 2010

(30) Foreign Application Priority Data
Jul. 29, 2009 (KR) 10-2009-0069241

(51) Int. Cl. H01L 31/0288; H01L 31/18

(52) U.S. Cl. 136/255; 438/71; 257/E31.13

(57) ABSTRACT

A photovoltaic cell substrate, a method of manufacturing the photovoltaic cell substrate, and a photovoltaic cell. The photovoltaic cell substrate includes a transparent substrate having a first surface-roughening film formed on one surface thereof and a transparent conductive film formed over the first surface-roughening film of the transparent substrate. The transparent conductive film is made of a metal oxide which is doped with a dopant.

### CROSS REFERENCE TO RELATED APPLICATION

The present application claims priority from Korean Patent Application Number 10-2009-0069241 filed on Jul. 29, 2010, the entire contents of which application are incorporated herein for all purposes by this reference.

### BACKGROUND OF THE INVENTION

1. Field of the Invention

The present invention relates to a photovoltaic cell substrate, a method of manufacturing the photovoltaic cell substrate, and a photovoltaic cell.

2. Description of Related Art

A photovoltaic cell is a key element in photovoltaic power generation, in which energy from sunlight is directly converted into electricity. Photovoltaic cells are applied in various fields, which include electrical and electronic appliances, the supply of electrical power to houses and buildings, and industrial power generation. The most basic photovoltaic cell has structure like a diode that has a pn junction. Photovoltaic cells can be categorized according to the material used in the light absorbing layer. Photovoltaic cells may be categorized into a silicon photovoltaic cell, which uses silicon as the light absorbing layer; a compound photovoltaic cell, which uses, for example, Copper Indium Selenide (CIS: CuInSe₂) or Cadmium Telluride (CdTe) as the light absorbing layer; a dye-sensitized photovoltaic cell, in which photosensitive dye, which excite electrons in response to the absorbing of visible light, are bonded to the surface of nano-particles of a porous layer; a stacked photovoltaic cell, in which, for example, a plurality of amorphous silicon layers are stacked on one another, etc. In addition, photovoltaic cells may be categorized into bulk photovoltaic cells (including single crystalline photovoltaic cells and polycrystalline photovoltaic cells) or thin film photovoltaic cells (including amorphous photovoltaic cells and polycrystalline photovoltaic cells).

At present, bulk photovoltaic cells which use polycrystalline silicon, occupy 90% or more of the whole market. However, the cost of using bulk photovoltaic cells for power generation is three to ten times as expensive as when using existing power generation techniques, such as thermal power generation technique, nuclear power generation technique, or hydraulic power generation technique. This is mainly attributable to the high cost of crystalline silicon and the high manufacturing cost of the crystalline silicon photovoltaic cell, which is complicated to manufacture. Therefore, in recent days, amorphous silicon (a-Si:H) and microcrystalline silicon (μc-Si:H) thin film photovoltaic cells are being actively studied and commercially distributed.

FIG. 1 is a cross-sectional view showing the structure of a photovoltaic cell using amorphous silicon as a light-absorbing layer in the related art.

As shown in the figure, the conventional amorphous silicon (e.g., a-Si:H) photovoltaic cell 110 includes a transparent substrate 111, a transparent conductive film 112, a p-type amorphous silicon (a-Si:H) layer 113, which is doped with a dopant, an i-type (intrinsic) amorphous silicon (a-Si:H) layer 114, which is not doped with a dopant, an n-type amorphous silicon (a-Si:H) layer 115, which is doped with a dopant, and a back reflector 116. In the i-type amorphous silicon (a-Si:H) layer 114, depletion occurs under the influence of the p-type and n-type amorphous silicon (a-Si:H) layers 113 and 115, thereby generating an electric field. An electron-hole pair created in the i-type amorphous silicon (a-Si:H) layer 114 in response to incident light (hν), is collected by the p-type amorphous silicon (a-Si:H) layer 113 and the n-type amorphous silicon (a-Si:H) layer 115 through the drift due to the internal electric field, thereby generating an electric current.

The microcrystalline silicon (μc-Si:H) is an intermediate material between single crystalline silicon and amorphous silicon, and has a crystal size ranging from tens to hundreds of nanometers. In the microcrystalline silicon, an amorphous phase is frequently present at the interface between crystals and, in most cases, carrier recombination occurs due to high defect density. The microcrystalline silicon (μc-Si:H) has an energy band gap of about 1.6 eV, which is substantially the same as that of the single crystalline silicon, and does not exhibit deterioration, which occurs in the amorphous silicon (a-Si:H) photovoltaic cell. The structure of the microcrystalline silicon (μc-Si:H) photovoltaic cell is very similar to that of the amorphous silicon (a-Si:H) photovoltaic cell, except for the light absorbing layer.

A single p-i-n junction thin film photovoltaic cell, which uses the amorphous silicon (a-Si:H) or the microcrystalline silicon (μc-Si:H) as the light absorbing layer, has many restrictions on its use in practice due to low light conversion efficiency. Therefore, a tandem photovoltaic cell or a triply stacked photovoltaic cell, which is fabricated by doubly or triply stacking the amorphous silicon (a-Si:H) or the microcrystalline silicon (μc-Si:H), is used, because it can raise open circuit voltage and improve light conversion efficiency by connecting the component photovoltaic cells in series.

FIG. 2 is a cross-sectional view showing the structure of a tandem photovoltaic cell of the related art.

As shown in the figure, the tandem photovoltaic cell 210 of the related art generally includes a transparent substrate 211, a transparent conductive film 212, a first pn junction layer 213, a tunneling pn junction layer 214, a second pn junction layer 215, and a back reflector 216.

In the tandem photovoltaic cell 210 of the related art, the first pn junction layer 213, having a predetermined band gap (e.g., E_{g}=1.9 eV), is disposed above the second pn junction layer 215 having a smaller band gap (e.g., E_{g}=1.42 eV), such that a photon having an energy of 1.42 eV<hν<1.9 eV is allowed to pass through the first pn junction layer 213 but is absorbed by the second pn junction layer 215. It is possible to realize higher light conversion efficiency by increasing the number of stacking. However, if the number of layers that are stacked is increased, there is a drawback in that the number of processes is increased, which leads to an increase in the process cost.

The transparent conductive film used in the photovoltaic cell is required to exhibit excellent light transmittance, electrical conductivity, and light trapping capability. In particular, in the amorphous silicon thin film photovoltaic cell, it is important to increase the light trapping capability as much as possible, since the amorphous silicon has low light absorptivity. In order to obtain the light trapping effect, the transparent conductive film for a photovoltaic cell has a textured structure on the surface thereof. The process of forming the textured structure on the surface of the transparent conductive film can be performed simultaneously with the process of forming the conductive film on the transparent substrate, or can be realized through wet etching of the conductive film formed over the transparent substrate.

However, in order to form the textured structure while forming the conductive film over the transparent substrate, Chemical Vapor Deposition (CVD) has to be conducted. The technology of simultaneously forming the textured structure through sputtering has not been established yet. Therefore, in order to form the textured structure, a method of forming a coating film by sputtering, followed by wet etching of the conductive film, is used. However, this method has a problem in that Indium Tin Oxide (ITO) or zinc oxide (ZnO), which is used in forming the conductive film, is wasted. In addition, ITO, which is generally used as a transparent conductive film, has problems of the continuously rising of the price of the main ingredient indium (In), which is a rare element, the high reducibility of indium in the hydrogen plasma process and resultant chemical instability, and the like.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a photovoltaic cell substrate, a method of manufacturing the photovoltaic cell substrate, and a photovoltaic cell, which can reduce manufacturing costs and raise photoelectric conversion efficiency and productivity.

In an aspect of the present invention, the photovoltaic cell substrate includes a transparent substrate having a first surface-roughening film formed on one surface thereof; and a transparent conductive film formed over the first surface-roughening film of the transparent substrate. The transparent conductive film is made of a metal oxide which is doped with a dopant.

In an exemplary embodiment of the invention, the transparent conductive film may include the dopant in an amount ranging from 0.1 to 15 by atomic percent, and has a thickness ranging from 450 nm to 900 nm.

In another exemplary embodiment of the invention, the photovoltaic cell substrate may further include a protective film formed over the transparent conductive film in order to improve moisture resistance of the transparent conductive film.

In a further exemplary embodiment of the invention, the transparent substrate may also have a second surface-roughening film formed on the other surface thereof.

In another aspect of the present invention, the photovoltaic cell includes the photovoltaic cell substrate as described above; and a light-absorbing layer. The light-absorbing layer absorbs incident light which has passed through the photovoltaic cell substrate.

In a further aspect of the present invention, the method of manufacturing the photovoltaic cell substrate includes the steps of: preparing a transparent substrate; forming a first surface-roughening film on one surface of the transparent substrate; and forming a transparent conductive film over the first surface-roughening film. The transparent conductive film is made of a metal oxide doped with a dopant.

As set forth above, since the surface-roughening film, which serves to realize a light trapping effect, is formed on the surface of the transparent substrate, the process of forming the textured structure, which has to be performed independently of the process of forming the transparent conductive film in the related art, is obviated and thus, the photovoltaic cell substrate, the method of manufacturing the photovoltaic cell substrate, and the photovoltaic cell have a useful effect of improving productivity. In addition, the cost of manufacturing the photovoltaic cell substrate is reduced by solving the problem of wasted material, which would otherwise occur in the process of forming the textured structure on a surface of the conductive film.

In addition, the photovoltaic cell substrate, the method of manufacturing the photovoltaic cell substrate, and the photovoltaic cell have a useful effect in that it is possible to form the transparent conductive film which exhibits high conductivity and light transmittance, at a low cost, since the transparent conductive film is mainly made of zinc oxide (ZnO) which is doped with a dopant.

Furthermore, the photovoltaic cell substrate, the method of manufacturing the photovoltaic cell substrate, and the photovoltaic cell have a useful effect in that it is possible to improve the light transmittance of the transparent conductive film by preventing incident light from being reflected from the other surface of the transparent substrate using the second surface-roughening film, since the second surface-roughening film is formed on the other surface of the transparent substrate.

The methods and apparatuses of the present invention have other features and advantages which will be apparent from, or are set forth in more detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a cross-sectional view showing the structure of a photovoltaic cell using amorphous silicon as a light-absorbing layer in the related art;

FIG. 2 is a cross-sectional view showing the structure of a tandem photovoltaic cell of the related art;

FIG. 3 is a cross-sectional view showing the structure of a photovoltaic cell substrate according to an exemplary embodiment of the invention;

FIG. 4 is a cross-sectional view showing the structure of a photovoltaic cell according to an exemplary embodiment of the invention; and

FIG. 5 is a flowchart showing a method of manufacturing a photovoltaic cell substrate according to an exemplary embodiment of the invention.

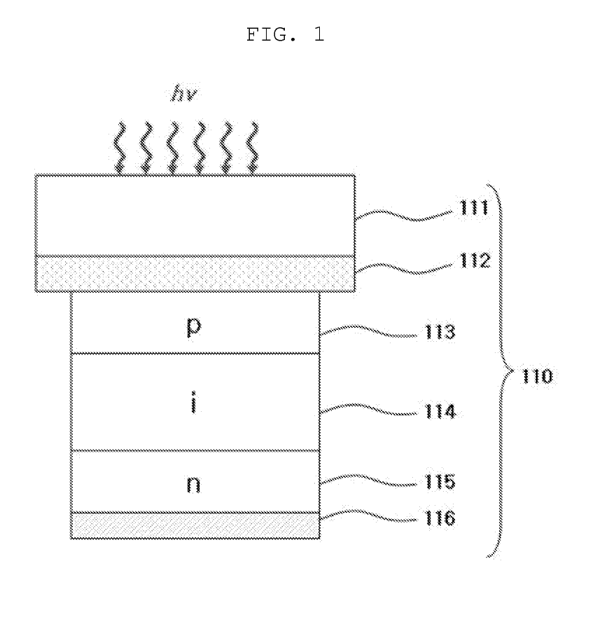

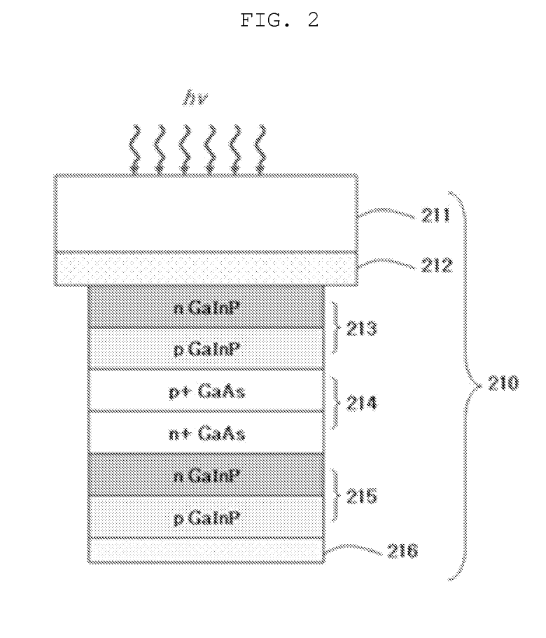

### DETAILED DESCRIPTION OF THE INVENTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments that may be included within the spirit and scope of the invention as defined by the appended claims.

Photovoltaic Cell Substrate

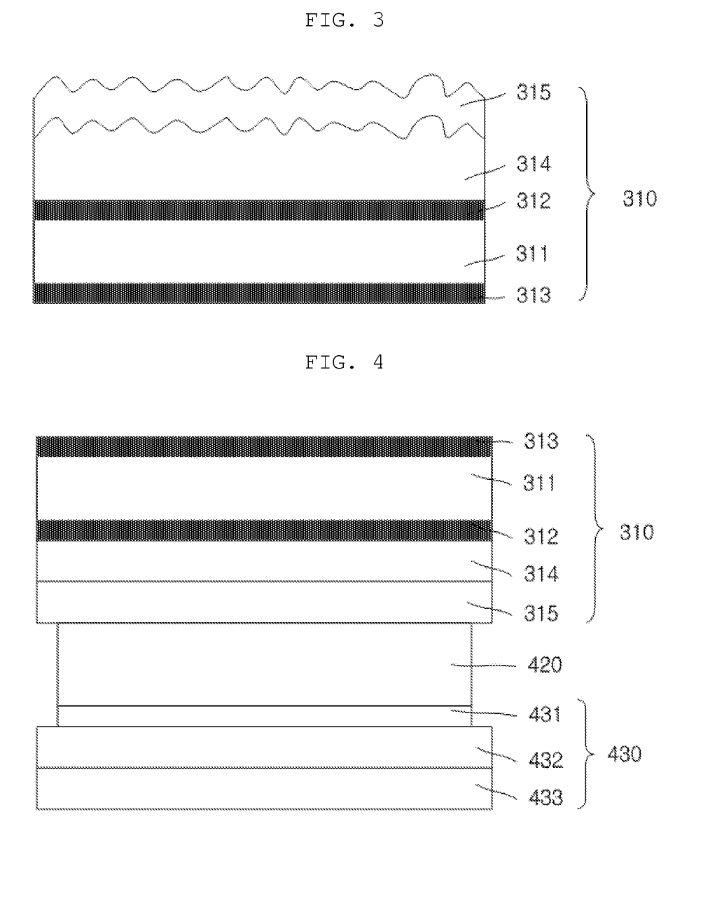

FIG. 3 is a cross-sectional view showing the structure of a photovoltaic cell substrate according to an exemplary embodiment of the invention.

As shown in FIG. 3, the photovoltaic cell substrate 310 includes a transparent substrate 311 which has first and second surface-roughening films 312 and 313 on the surfaces thereof, and a transparent conductive film 314. Herein, the surface-roughening film indicates a film that has small and irregular recesses/protrusions in a nanometer scale, the recesses/protrusions being distributed on the surface of the transparent substrate 311.

The transparent substrate 311 serves to protect the photovoltaic cell, and can be realized as having an iron content of 0.06% or less, a thickness of 5 mm or less, and a light transmittance of 90% or more. In another example, the transparent substrate 311 can be formed using a heat curing or Ultraviolet (UV) curing organic substrate, which is generally made of a polymer-based material. Examples of the polymer-based material may include Polyethylene Terephthalate (PET), acryl, Polycarbonate (PC), Urethane Acrylate (UA), polyester, Epoxy Acrylate (EA), brominate acrylate, Polyvinyl Chloride (PVC), and the like.

The first surface-roughening film 312 serves to improve the capability to trap incident light. The second surface-roughening film 313 prevents incident light from being reflected from the surface of the transparent substrate 311, thereby improving the transmittance of light that will be incident on the transparent conductive film 314 through the transparent substrate 311.

In an example, the first and second surface-roughening films 312 and 313 can be formed by etching the transparent substrate 311 using a chemical solution (e.g., H₂SiF₆). In another example, the first and second surface-roughening films 312 and 313 can be formed by coating with a composition solution, which can form silicon oxide (SiO₂), on the surface of the transparent substrate 311, so that the solution forms porous oxide through hydration in the air.

The transparent conductive film 314 serves to conduct an electrical current generated by photoelectric conversion, and is made of a material that has high electric conductivity and high light transmittance. In an exemplary embodiment, the transparent conductive film 314 is formed over the first surface-roughening film 312 of the transparent substrate 311, and includes zinc oxide which is doped with a dopant, as a main ingredient. Here, the dopant can be one selected from among fluorine (F), aluminum (Al), gallium (Ga), and boron (B).

In general, it is easy to control the electrical-optical properties of zinc oxide depending on the kind of the dopant, since it can be easily doped and has a narrow conductivity band. In addition, zinc oxide is stable in a hydrogen plasma reducing atmosphere. However, zinc oxide itself has high electrical resistivity, and its characteristics tend to degrade as time passes. For example, as time passes, zinc oxide bonds with oxygen, thereby increasing electrical resistivity.

In an exemplary embodiment, it is preferred that the transparent conductive film 314 include the dopant in an amount ranging from 0.1 to 15 by atomic percent, and that the transparent conductive film 314 have a thickness ranging from 450 nm to 900 nm. In this embodiment, the transparent conductive film 314 ensures that light transmittance is high and that light absorption attributable to the dopant is low. In addition, it is possible to prevent electrical resistivity of the transparent conductive film from increasing due to the combination of zinc oxide and oxygen.

In an exemplary embodiment of the invention, the photovoltaic cell substrate 310 can also include a protective film 315, which is formed over the transparent conductive film 314 in order to improve the moisture resistance of the transparent conductive film 314. The characteristic of zinc oxide, which is used as the main ingredient of the transparent conductive film 314, tends to be degraded under high humidity. The protective film 315 is required to exhibit excellent electrical conductivity and light transmittance while protecting zinc oxide from moisture. For example, the protective film 315 has a thickness ranging from 15 nm to 25 nm, and can include one material selected from among SnO₂:F, Indium Tin Oxide (ITO), TiO₂, Nb₂O₅, Ta₂O₅, Ti₂O₃, Si₃N₄, and Ti₃O₅.

Table 1 below presents the results obtained by measuring the effect of trapping incident light, which has passed through a photovoltaic cell substrate of an example of the invention, in terms of surface roughness, haze values, and photoelectric conversion efficiency.

TABLE 1

| RMS | Thickness of | | Photoelectric |
|---|---|---|---|
| surface | surface-roughening | | conversion |
| roughness | film | Haze | efficiency η (%) |
| 30 (nm) | 100 nm | 0.7 | 6.0 |
| 72 (nm) | 150 nm | 15 | 7.1 |
| 127 (nm) | 200 nm | 44 | 8.2 |

Here, the RMS surface roughness indicates a value of root mean square surface roughness of a transparent conductive film, which was measured after a glass substrate, a surface-roughening film, and the transparent conductive film were formed in sequence. The transparent conductive film had a thickness of 700 nm, and amorphous silicon (a-Si:H) was used for the light-absorbing layer of the photovoltaic cell.

As seen in Table 1 above, it is apparent that the RMS surface roughness, the haze value, and the photoelectric conversion efficiency of the transparent conductive film increase, as the thickness of the surface-roughening film increases. Accordingly, the photovoltaic cell substrate according to an exemplary embodiment of the invention is advantageous in that it is possible to improve the light trapping effect and thus improve the photoelectric conversion efficiency without the textured structure formed on a surface of the transparent conductive film in the related art, since the surface-roughening film is formed on the surface of the transparent substrate.

Photovoltaic Cell

FIG. 4 is a cross-sectional view showing the structure of a photovoltaic cell according to an exemplary embodiment of the invention.

As shown in FIG. 4, the photovoltaic cell of this embodiment includes a first photovoltaic cell substrate 310, a light-absorbing layer 420, and second photovoltaic cell substrate 430.

The first photovoltaic cell substrate 310 includes a transparent substrate 311 which has a first surface-roughening film 312 and a second surface-roughening film 313 on the surfaces thereof, a transparent conductive film 314, and a protective film 315. The transparent substrate 311 which has the first and second surface-roughening films 312 and 313 on the surfaces thereof, the transparent conductive film 314, and the protective film 315 are formed in the same way as described above with reference to FIG. 3.

The light-absorbing layer 420 absorbs light energy Irv, incident from the first photovoltaic cell substrate 310, and coverts it into an electric current. It is preferred that the light-absorbing layer 420 be made of a material that has high photoelectric conversion efficiency. For example, the light-absorbing layer 420 can be made of one selected from among amorphous silicon, a compound semiconductor, a dye-sensitized semiconductor, and a stacked structure of two or more thereof.

The light-absorbing layer 420 can be formed of hydrogenated amorphous silicon (a-Si:H) or hydrogenated microcrystalline silicon (μc-Si:H). The compound silicon can be formed of a I-III-VI group compound semiconductor (e.g., CuInSe₂), a II-VI group compound semiconductor (e.g., CdTe, ZnSe, ZnS), or a II-V group compound semiconductor (e.g., GaAs, InAs, InP, or InSb).

In the dye-sensitized semiconductor, photosensitive dye molecules, which excite electrons in response to the absorbing of visible light, are bonded to the surface of nano-particles of a porous layer between the first photovoltaic cell substrate 310 and the second photovoltaic cell substrate 430. In addition, a redox electrolyte (e.g., I⁻/I³⁻) fills the remaining space between the first photovoltaic cell substrate 310 and the second photovoltaic cell substrate 430. Examples of a dye, bonded to the surface of the nano-particles of the porous layer, can be materials that can absorb visible light, and include a compound in the form of a metal complex, which contains one or more selected from among Al, Pt, Pd, Eu, Pb, or Ir, or a Ru complex.

The second photovoltaic cell substrate 430 can include a back reflector 431, a transparent conductive film 432, and a back cover 433.

The back reflector 431 serves to improve photoelectric conversion efficiency by preventing light incident on the light-absorbing layer 420, from being dissipated. The back reflector 431 can be a metal film, which is made of one or more selected from among Mo, Al, Ag, Au, Pt, Cu, and Ni.

The transparent conductive film 432 serves as an electrode that conducts an electrical current, generated by photoelectric conversion, and is formed to coat the back cover 433 by sputtering, Chemical Vapor Deposition (CVD), Spray Pyrolysis Deposition (CVD), or the like. The transparent conductive film 432 can be made of one material selected from among Indium Tin Oxide (IT), Fluorine-doped Tin Oxide (FTO), zinc oxide (ZnO), Antimony-doped Tin Oxide (ATO), and Tin Oxide (TO), or can be a multilayer film of the same materials.

The back cover 433 can be a common transparent substrate, such as a soda-line glass substrate or a borosilicate glass substrate, or a heat curing or Ultraviolet (UV) curing organic substrate, which is generally made of a polymer-based material. Examples of the polymer-based material may include Polyethylene Terephthalate (PET), acryl, Polycarbonate (PC), Urethane Acrylate (UA), polyester, Epoxy Acrylate (EA), brominate acrylate, Polyvinyl Chloride (PVC), and the like.

Method of Manufacturing Photovoltaic Cell Substrate

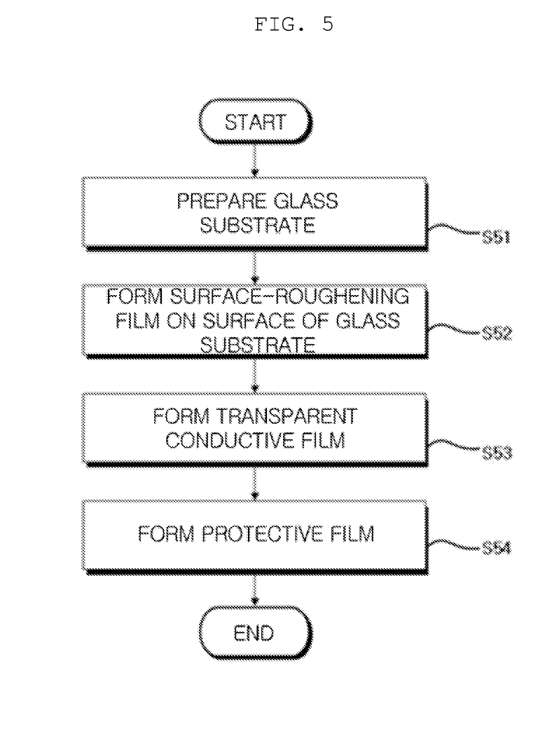

FIG. 5 is a flowchart showing a method of manufacturing a photovoltaic cell substrate according to an exemplary embodiment of the invention.

As shown in FIG. 5, first, a transparent substrate is prepared in S51. The transparent substrate can be a glass substrate that has an iron content of 0.02% or less, a thickness of 5 mm or less, and a light transmittance of 90% or more. In another example, the transparent substrate can be a heat curing or Ultraviolet (UV) curing organic substrate, which is generally made of a polymer-based material. Examples of the polymer-based material may include Polyethylene Terephthalate (PET), acryl, Polycarbonate (PC), Urethane Acrylate (UA), polyester, Epoxy Acrylate (EA), brominate acrylate, Polyvinyl Chloride (PVC), and the like.

Afterwards, a surface-roughening film is formed on a surface of the transparent substrate in S52. In an example, the surface-roughening film can be formed by etching the transparent substrate 311 using a chemical solution (e.g., H₂SiF₆). In another example, the surface-roughening film can be formed by coating with a composition solution, which can form silicon oxide (SiO₂), on the surface of the transparent substrate, so that the solution forms porous oxide through hydration in the air. Only one surface-roughening film can be formed on the surface of the transparent substrate or a pair of surface-roughening films can be formed on both surfaces of the transparent substrate.

Next, in S53, a transparent conductive film is formed over the surface-roughening film, which is formed on the surface of the transparent substrate. The transparent conductive film can be formed by sputtering, evaporation, electron beam evaporation, Metal Organic Chemical Vapor Deposition (MOCVD), pyrolysis, spray pyrolysis, or the like. The transparent conductive film is made of zinc oxide which is doped with a dopant.

Since zinc oxide can be easily doped and has a narrow conductivity band, it is easy to control the electrical-optical properties of the transparent conductive film depending on the kind of the dopant. In addition, zinc oxide is stable in a hydrogen plasma reducing atmosphere. However, zinc oxide itself has high electrical resistivity, and its characteristics tend to degrade as time passes.

In an exemplary embodiment, it is preferred that the transparent conductive film formed in step S53 include the dopant in an amount ranging from 0.1 to 15 by atomic percent, and that it have a thickness ranging from 450 nm to 900 nm. Here, the dopant can be one selected from among fluorine (F), aluminum (Al), gallium (Ga), and boron (B). In this embodiment, the transparent conductive film ensures that light transmittance is high and that light absorption attributable to the dopant is low. In addition, it is possible to prevent electrical resistivity of the transparent conductive film from increasing due to the combination of zinc oxide and oxygen.

Afterwards, in S54, a protective film is formed over the transparent conductive film. The characteristic of zinc oxide, which is used as the main ingredient of the transparent conductive film, tends to be degraded under high humidity. The protective film is required to exhibit excellent electrical conductivity and light transmittance while protecting zinc oxide from moisture. In an example, it is preferred that the protective film includes one material selected from among SnO₂:F, Indium Tin Oxide (ITO), TiO₂, Nb₂O₅, Ta₂O₅, Ti₂O₃, Si₃N₄, and Ti₃O₅, and have a thickness ranging from 15 nm to 25 nm.

The foregoing descriptions of specific exemplary embodiments of the present invention have been presented for the purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A photovoltaic cell substrate comprising:
a transparent substrate having a first surface-roughening film formed on one surface thereof; and
a transparent conductive film formed over the first surface-roughening film of the transparent substrate, wherein the transparent conductive film is made of a metal oxide which is doped with a dopant.

2. The photovoltaic cell substrate according to claim 1, wherein the transparent conductive film includes the dopant in an amount ranging from 0.1 to 15 by atomic percent, and has a thickness ranging from 450 nm to 900 nm.

3. The photovoltaic cell substrate according to claim 1, wherein the metal oxide which is doped with the dopant, is zinc oxide, and the dopant is one selected from the group consisting of fluorine, aluminum, gallium, and boron.

4. The photovoltaic cell substrate according to claim 1, further comprising a protective film formed over the transparent conductive film in order to improve moisture resistance of the transparent conductive film.

5. The photovoltaic cell substrate according to claim 4, wherein the protective film has a thickness ranging from 15 nm to 25 nm, and comprises one material selected from the group consisting of SnO₂:F, indium tin oxide, TiO₂, Nb₂O₅, Ta₂O₅, Ti₂O₃, Si₃N₄, and Ti₃O₅.

6. The photovoltaic cell substrate according to claim 1, wherein the transparent substrate further comprises a second surface-roughening film formed on the other surface thereof.

7. A photovoltaic cell comprising:
a photovoltaic cell substrate comprising a transparent substrate having a first surface-roughening film formed on one surface thereof and a transparent conductive film formed over the first surface-roughening film of the transparent substrate, wherein the transparent conductive film is made of a metal oxide which is doped with a dopant; and
a light-absorbing layer absorbing incident light which has passed through the photovoltaic cell substrate.

8. The photovoltaic cell according to claim 7, wherein the light-absorbing layer comprises one selected from the group consisting of amorphous silicon, a compound semiconductor, a dye-sensitized semiconductor, and a laminated structure of two or more thereof.

9. A method of manufacturing a photovoltaic cell substrate, the method comprising:
preparing a transparent substrate;
forming a first surface-roughening film on one surface of the transparent substrate; and
forming a transparent conductive film over the first surface-roughening film, wherein the transparent conductive film is made of a metal oxide which is doped with a dopant.

10. The method according to claim 9, wherein the first surface-roughening film is formed by etching the transparent substrate or coating with porous oxide.

11. The method according to claim 9, further comprising forming a second surface-roughening film on the other surface of the transparent substrate.

12. The method according to claim 11, wherein the second surface-roughening film is formed by etching the transparent substrate or coating with porous oxide.
